(19) United States
(12) Patent Application Publication
(10) Pub. No.: US 2015/0287874 A1
(43) Pub. Date: Oct. 8, 2015

(54) METAL TEMPLATE STRUCTURE

(71) Applicant: FAITHFUL PRINTING EQUIPMENT & SUPPLY CO., LTD., New Taipei City (TW)

(72) Inventors: Yi-Yang LIN, New Taipei City (TW); Wei-Chien CHIANG, New Taipei City (TW)

(21) Appl. No.: 14/678,646

(22) Filed: Apr. 3, 2015

(30) Foreign Application Priority Data
Apr. 3, 2014 (TW) 103205871

(51) Int. Cl. H01L 31/18; B05B 1/14; H01L 31/0224

(52) U.S. Cl. CPC H01L 31/18; H01L 31/022433; B05B 1/14

(57) ABSTRACT

A metal template structure at least includes a frame, a supporting stainless wire cloth is disposed at an inner edge of the frame, a metal template is disposed on the supporting stainless wire cloth, and falling holes arranged in a printing shape are disposed on the metal template. The present invention is characterized in that: a feeding guide portion extends upwards from an upper periphery of each falling hole, an aperture of the feeding guide portion is greater than an aperture of the falling hole, and a periphery of the feeding guide portion and a periphery of the falling hole are connected in different forms such as a right angle surface, an inclined surface or a concave surface. By using a large aperture of the feeding guide portion and increasing the feeding guide portion, the thickness of the metal template is increased, so that more slurry can pass through the falling holes smoothly during printing, thereby achieving optimal falling effect.

### CROSS-REFERENCE TO RELATED APPLICATION

This application claims the benefit of Taiwan Patent Application No. 103205871, filed on Apr. 3, 2014, which is hereby incorporated by reference for all purposes as if fully set forth herein.

### BACKGROUND

1. Technical Field

The present invention relates to a metal template structure, and more particularly, to a metal template having feeding guide portions additionally disposed on falling holes, so as to increase the aperture area during slurry falling, thereby obtaining optimal falling effect, and achieving high printing thickness of a finger electrode in a solar cell.

2. Related Art

Referring to FIG. 1 and FIG, 2, a schematic structural view of a conventional metal template structure and a schematic implementation view of the metal template structure are respectively shown. Accordingly, the conventional metal template structure 10 includes a frame 11, a supporting stainless wire cloth 12 is disposed at an inner edge of the frame 11, a metal template 20 is disposed on the supporting stainless wire cloth 12, and a plurality of falling holes 21 arranged in a printing shape is disposed on the metal template 20; during implementation, the metal template 20 covers a substrate 30, an opening is formed in the supporting stainless wire cloth 12 corresponding to the metal template 20, slurry 40 is placed on the metal template 20, and a scraper is used to scrape the slurry into the falling holes 21, so that the slurry 40 passes through the falling holes 21 and attaches to the substrate 30 for printing.

When printing a solar cell, the smaller width and larger thickness of a finger electrode on the substrate 30 result in higher solar energy conversion efficiency; however, the slurry 40 (for example, silver paste) for printing the solar cell electrode has high stickiness, and the falling hole 21 on the conventional metal template 20 has an aperture contacting the scraper the same size as an aperture close to the substrate 30, when the slurry 40 is scraped, the slurry 40 easily adheres to the aperture of the falling hole 21, so that the slurry cannot completely pass through the falling hole 21, resulting in incomplete penetrating or even incapability of penetrating, and therefore, ideal finger electrode printing thickness cannot be achieved, and the solar energy conversion efficiency is reduced.

Moreover, a ratio between the aperture of the falling hole 21 of the conventional metal template 20 and the thickness of the metal template 20 (about 20-50 μm) is less than or equal to 1.2, that is, the thickness of the metal template 20 cannot be greater than 1.2 times of the width of the aperture of the falling hole 21, which is mainly limited by a manufacturing method of processing falling holes on the metal template 20 at this stage, and in consideration that during a single layer structure printing process only using the metal template 20 as a printing template, printing quality is unstable because the metal template 20 lacks supporting, so that the falling holes 21 of the conventional metal template 20 has the limit on aspect ratio, the ratio between the aperture of the falling hole 21 and the thickness of the metal template 20 cannot be greater than 1.2, and it is difficult to improve the printing quality during actual application.

### SUMMARY

Accordingly, in order to overcome the above defects, the present invention is directed to solve the problem that a falling hole on a conventional metal template has an aperture contacting a scraper the same size as an aperture close to a substrate, the aperture width of the falling hole contacting the scraper is not large enough so that slurry easily adheres to the aperture of the falling hole, thereby resulting in incomplete falling or even incapability of penetrating, and therefore the ideal printing thickness cannot be achieved.

In order to achieve the above objective, the present invention discloses a metal template structure, which is characterized in that, a feeding guide portion extends upwards from an upper periphery of each falling hole, an aperture of the feeding guide portion is greater than an aperture of the falling hole, and the shape of a junction surface of an upper periphery of the feeding guide portion and an upper periphery of the falling hole may assume an inclined surface, a concave surface, or a right angle surface according to the feeding guide portion and different properties of slurry.

The present invention has the advantage that, by using the feeding guide portions having greater aperture, when slurry is scraped, more slurry falls into the falling holes, so as to keep the optimal printing thickness; moreover, the increased feeding guide portion increases the thickness of the metal template, so that the ratio between the aperture of the falling hole and the thickness of the metal template is greater than 1.2, thereby achieving better printing quality.

### BRIEF DESCRIPTION OF THE DRAWINGS

The disclosure will become more fully understood from the detailed description given herein below for illustration only and thus are not limitative of the disclosure, and wherein:

FIG. 1 is a schematic view of a conventional metal template structure,

FIG. 2 is a schematic implementation view of a conventional metal template structure,

FIG. 3 is a schematic view of a metal template structure according to the present invention,

FIG. 4 is a schematic implementation view of a metal template structure according to the present invention,

FIG. 5 is a first local sectional view of a feeding guide portion in a metal template structure according to the present invention,

FIG. 6 is a second local sectional view of a feeding guide portion in a metal template structure according to the present invention,

FIG. 7 is a third local sectional view of a feeding guide portion in a metal template structure according to the present invention,

FIG. 8 is a first local sectional view of a falling hole in a metal template structure according to the present invention, and

FIG. 9 is a second local sectional view of a falling hole in a metal template structure according to the present invention.

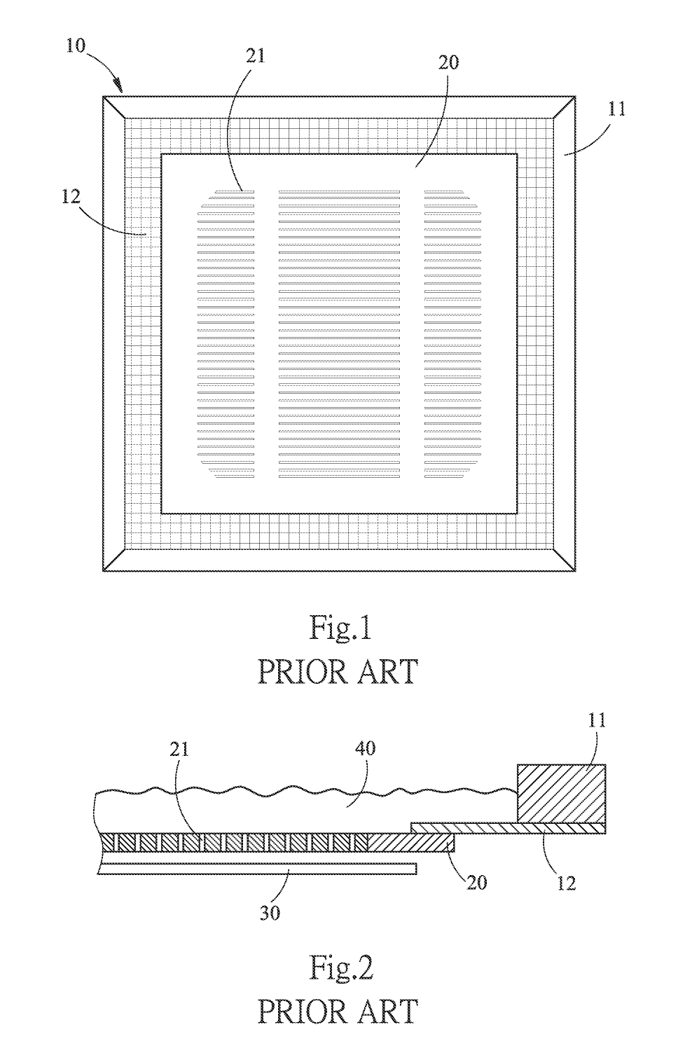

### DETAILED DESCRIPTION

Detailed content and technical descriptions of the present invention are further illustrated through embodiments, but it should he understood that, the embodiments are only described as examples, and are not intended to limit the present invention.

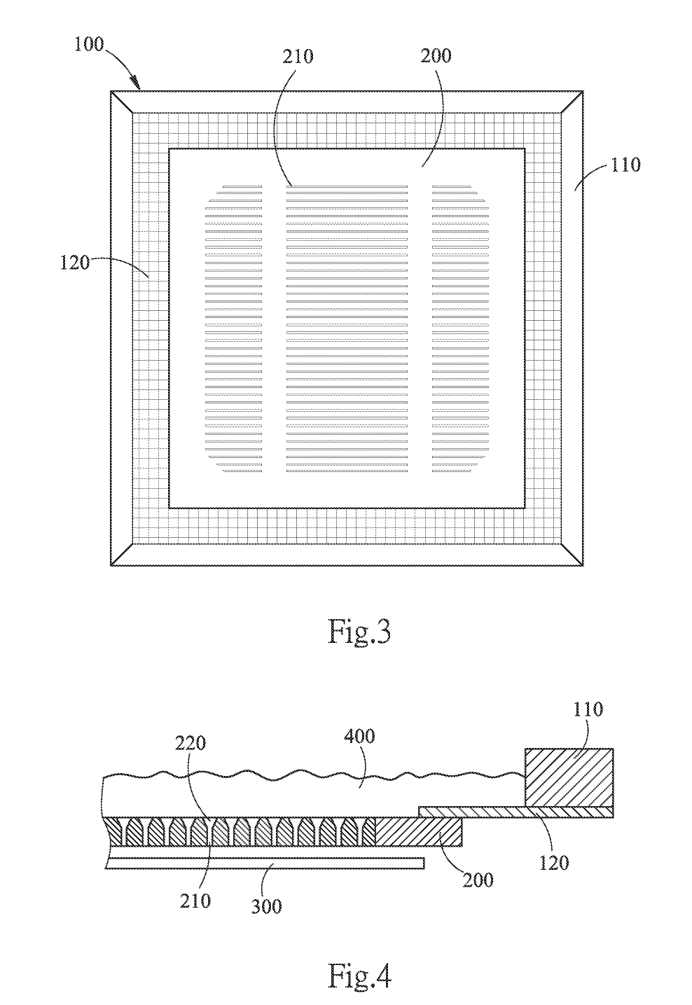

Referring to FIG. 3 and FIG. 4, a schematic view of a metal template structure according to the present invention and a schematic implementation view of the metal template structure are shown respectively. The present invention provides a metal template structure 100, the metal template structure 100 at least includes a frame 110, a supporting stainless wire cloth 120 is disposed at an inner edge of the frame 110, a metal template 200 is disposed on the supporting stainless wire cloth 120, and a plurality of falling holes 210 arranged in a printing shape is disposed on the metal template 200, where a feeding guide portion 220 extends upwards from an upper periphery of each falling hole 210 on the metal template 200, and an aperture of the feeding guide portion 220 is greater than an aperture of the falling hole 210.

During implementation, a surface of the metal template 200 provided with the feeding guide portion 200 is placed upwards (the upper surface is generally referred to as a scraper surface), a substrate 300 is placed under the metal template 200 (the lower surface is generally referred to as an object contact surface), slurry 400 is placed in the range of the supporting stainless wire cloth 120 defined by the frame 110, and a scraper is used to scrape the slurry 400 to the feeding guide portion 220 on the metal template 200, so that the slurry 400 flows to the falling hole 210 through the feeding guide portion 220, and the slurry 400 forms a printing image on the substrate 300 through the arrangement of the falling holes 210.

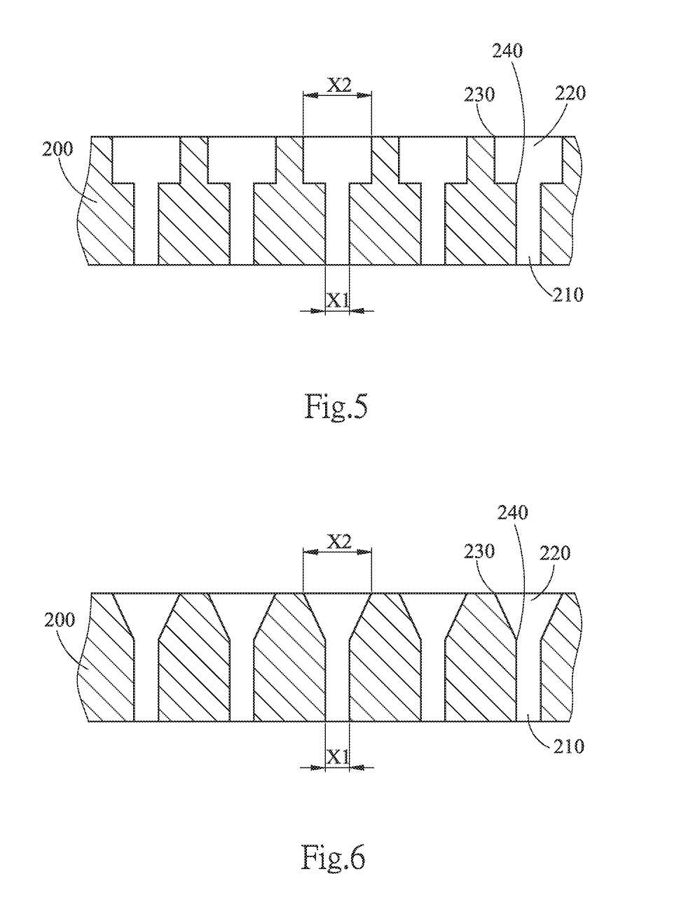

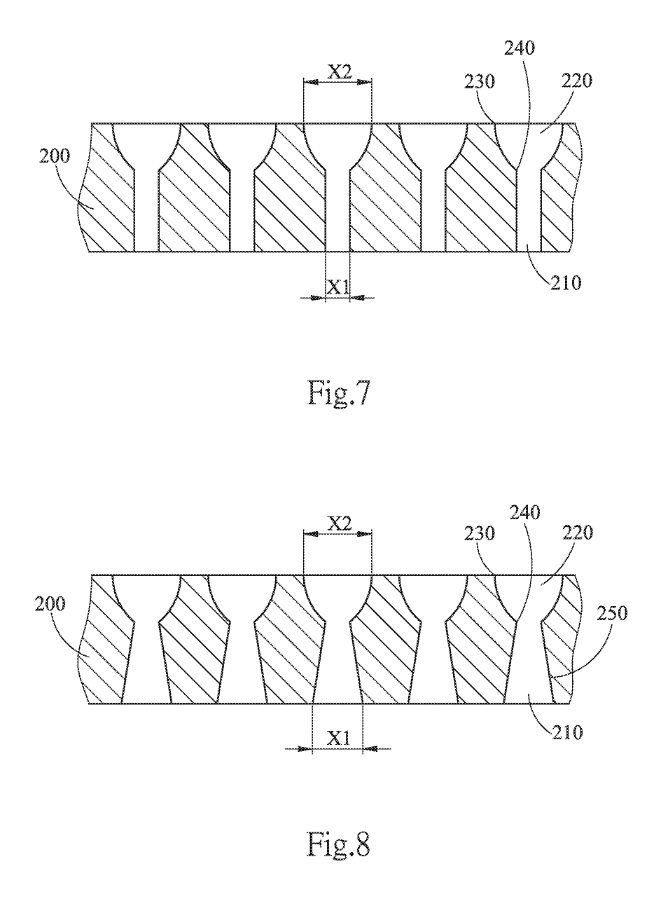

Referring to FIG, 5, FIG. 6 and FIG. 7, local sectional views of feeding guide portions in different forms of the metal template structure according to the present invention are shown. In order to match stickiness and property of different slurry 400, the shape of the feeding guide portion 220 may vary, and different spatial forms of the feeding guide portion 220 may be presented through plane connection in different shapes by a guide portion upper periphery 230 and a falling hole upper periphery 240. When the falling hole upper periphery 240 and the guide portion upper periphery 230 are connected with two orthogonal surfaces, the feeding guide portion 220 assumes a rectangular space (as shown in FIG. 5); When the falling hole upper periphery 240 and the guide portion upper periphery 230 are connected with an inclined surface, the feeding guide portion 220 assumes a funnel-shaped space (as shown in FIG. 6); and when the falling hole upper periphery 240 and the guide portion upper periphery 230 are connected with a concave surface, the feeding guide portion 220 assumes a concave space (as shown in FIG. 7).

Further, feeding apertures X2 of the feeding guide portions 220 are all greater than falling apertures X1 of the falling holes 210, so that when the slurry 400 is scraped to the feeding aperture X2, because the feeding aperture X2 is greater, the area for penetrating is increased, and during implementation, more slurry 400 is easily scraped to the feeding guide portions 220, and the feeding guide portions 220 guides the slurry 400 into the falling holes 210, thereby improving the penetrating rate of the slurry 400, so as to achieve the optimal printing line thickness.

During implementation, a material for forming the feeding guide portions 220 may be a metal material of the metal template 200 through extension or may be an additional polymer material, and a method for forming the falling guide portions 220 is not limited to laser processing, etching, electroforming, or forming by jointing the polymer material or another heterogeneous material. By forming the feeding guide portions 220, when being provided with the falling holes 210 having the same falling aperture X1, the metal template 200 in the present invention has increased thickness (about 5-50 μm), and the thicker metal template 200 has better stability; therefore, the optimal printing quality may be achieved during implementation because of the good stability.

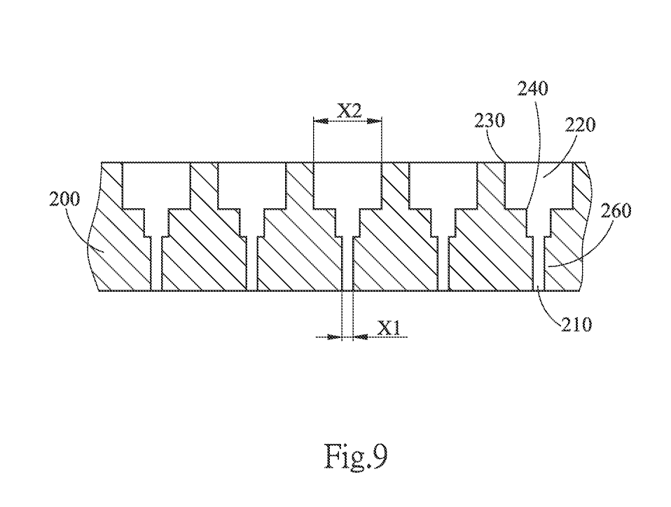

Furthermore, referring to FIG. 8 and FIG. 9, local sectional views of falling holes in different forms of the metal template structure according to the present invention are shown respectively, and it is disclosed that the width of a printed line is changed by different forms of falling holes 210. An inner side wall 250 of the falling hole 210 is a downwards opening inclined surface, a lower aperture of the falling hole 210 is greater than an upper aperture of the falling hole 210 (as shown in FIG. 8), and when the slurry 400 flows from the upper aperture to the lower aperture, the aperture of the falling hole 210 gradually becomes wider, and the line width of a printed image is wide, but the falling aperture X1 of the falling hole 210 is still less than the feeding aperture X2 of the feeding guide portion 220.

Furthermore, a protrusion 260 is disposed on the inner side wall of each of the falling holes, and a bottom end of the protrusion 260 extends to a bottom of the falling hole 210 (as shown in FIG. 9), that is, the lower aperture of the falling hole 210 is reduced through the protrusion 260, and by using the falling holes 210 having smaller falling aperture X1, the line width of the printed image may be thinner during implementation.

Therefore, the present invention adds the design of the feeding guide portions 220, which increases the penetrating rate of the slurry 400 flowing to the falling holes 210, so that when the slurry is scraped, more slurry 400 falls into the falling holes 210, thereby achieving the optimal printing line thickness. Moreover, because of the feeding guide portions 220, the falling holes 210, when having the same falling aperture X1, increase the thickness of the metal template 200, the thicker metal template 200 has better stability, and good stability may achieve better printing quality.

The present invention is disclosed through preferred embodiments in the foregoing text, however, those skilled in the art should understand that the embodiments are merely for the purpose of describing the present invention, but are not intended to limit the present invention. It should be noted that, equivalent variations and replacements made to the above embodiments shall fall within the scope of the present invention as specified in the following claim.

What is claimed is:

1. A metal template structure, comprising a supporting stainless wire cloth disposed at an inner edge of a frame, a metal template disposed on the supporting stainless wire cloth, and a plurality of falling holes arranged in a printing shape disposed on the metal template, wherein:
a feeding guide portion extends upwards from an upper periphery of each falling hole on the metal template, and an aperture of the feeding guide portion is greater than an aperture of the falling hole.

2. The metal template structure of claim 1, wherein each of the falling hole upper peripheries and each of the guide portion upper peripheries are connected with two orthogonal surfaces.

3. The metal template structure of claim 1, wherein each of the falling hole upper peripheries and each of the guide portion upper peripheries are connected with an inclined surface.

4. The metal template structure of claim 1, wherein each of the falling hole upper peripheries and each of the guide portion upper peripheries are connected with a concave surface.

5. The metal template structure of claim 1, wherein an inner side wall of each falling hole is a downwards opening inclined surface, and a lower aperture of each falling hole is less than an aperture of the feeding guide portion.

6. The metal template structure of claim 1, wherein a protrusion is further disposed on the inner side wall of each of the falling holes, and a bottom end of the protrusion extends to a bottom of the falling hole.
